(19) United States
(12) Patent Application Publication
(10) Pub. No.: US 2005/0196924 A1
(43) Pub. Date: Sep. 8, 2005

(54) Semiconductor device and its manufacture method

(75) Inventor: Atsushi Mimura, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/125,398

(22) Filed: May 6, 2005

Related U.S. Application Data
(63) Continuation of application No. PCT/JP03/04048, filed on Mar. 28, 2003.

(51) Int. Cl. H01L 21/336; H01L 31/0392; H01L 27/01; H01L 27/12

(52) U.S. Cl. 438/282

(57) ABSTRACT

A first gate insulating film is formed on an SOI layer made of semiconductor of an SOI substrate stacking a supporting substrate, a buried insulting layer and the SOI layer in this order recited. A first gate electrode is formed on the first gate insulating film. The buried insulating layer positioned below the first gate electrode is removed to expose a bottom of the SOI layer. A second gate insulating film is formed on the exposed bottom of the SOI layer. A second gate electrode is formed on a surface of the second gate insulating film.

### CROSS REFERENCE TO RELATED APPLICATION

This application is a Continuation Application of PCT/JP03/004048 filed on Mar. 28, 2003, the entire contents of which are incorporated herein by reference.

### TECHNICAL FIELD

The present invention relates to a semiconductor device and its manufacture method, and more particularly to a double-gate type transistor having a gate electrode on both sides of a channel region and its manufacture method.

### BACKGROUND ART

A silicon on insulator (SOI) transistor formed on an SOI substrate has recently drawn attention as potent semiconductor elements realizing a high speed and low power consumption LSI. Studies and developments have been conducted concentrating particularly upon a complete depletion type SOI transistor having a completely depleted body region under a channel.

As compared to a transistor on a bulk substrate and a partial depletion SOI transistor leaving a non-depleted region at the bottom of a body region, a complete depletion SOI transistor has a small sub-threshold coefficient (a gate voltage change necessary for increasing a drain current by one digit) so that a lower voltage operation is possible. Further, a higher speed operation is possible because the junction capacitance is very small between a source and a drain and between a substrate and a well.

In order to realize a complete depletion state of a single gate type SOI transistor, a thickness of a body inclusive of a channel is required to be one third or thinner than a gate length. If the gate length is 20 nm or shorter under miniaturization of transistors, a thickness of the body is required to be made thinner to about several nm. In this case, the impurity concentration in a well is required to be set high in order to control a threshold voltage, which is not desirable from the viewpoint of a carrier mobility.

In a double-gate type SOI transistor having a channel sandwiched between upper and lower gate electrodes, a complete depletion state can be realized if the thickness of a body is two thirds or thinner than the gate length. A threshold voltage can be controlled by one gate electrode. In a double-gate type transistor having a fin structure, since two gate electrodes are electrically shorted, it is impossible to control a threshold voltage by one gate electrode.

Although a complete depletion double-gate type transistor is considered a promising semiconductor element, its manufacture is difficult. It is necessary to align the positions of two gates. If the position of a gate electrode is misaligned, superposition of the gate electrode upon the source/drain regions occurs so that a parasitic capacitance increases and the performance of a high speed operation of a double-gate type transistor is lost.

The following Patent Document discloses a manufacture method for a double-gate type transistor capable of aligning the positions of two gate electrodes. This method, however, requires a special process not used in conventional semiconductor processes, leaving many issues to be solved for mass production.

(Patent Document) Japanese Patent Laid-open Publication No. 2000-277745

An object of this invention is to provide a semiconductor device capable of following conventional semiconductor processes and easily aligning the positions of two gate electrodes, and its manufacture method.

### DISCLOSURE OF THE INVENTION

According to one aspect of the present invention, there is provided a manufacture method for a semiconductor device, comprising steps of: (a) forming a first gate insulating film on an SOI layer made of semiconductor of an SOI substrate stacking a supporting substrate, a buried insulting layer and the SOI layer in this order recited; (b) forming a first gate electrode on the first gate insulating film; (c) removing the buried insulating layer positioned below the first gate electrode to expose a bottom of the SOI layer; (d) forming a second gate insulating film on the exposed bottom of the SOI layer; and (e) forming a second gate electrode on a surface of the second gate insulating film.

According to another aspect of the present invention, there is provided a semiconductor device comprising: a semiconductor film having top and bottom surfaces and defining a channel region, and a source region and a drain region on both sides of the channel region; a first gate insulating film formed on an upper surface of the channel region of the semiconductor film; a first gate electrode formed on the first gate insulating film; a first insulating film of insulating material formed on bottom surfaces of the source region and drain region of the semiconductor film; a second gate insulating film covering a bottom surface of the channel region of the semiconductor film and a surface of the first insulating film; and a second gate electrode formed on the second gate insulating film.

The first insulating film suppresses an increase in a parasitic capacitance between the second gate electrode and the source/drain regions.

### BRIEF DESCRIPTION OF THE DRAWINGS

FIG. 1A is a plan view (first plan view) illustrating a manufacture process for a semiconductor device according to a first embodiment, and FIGS. 1B and 1C are cross sectional views taken along one-dot chain lines B1-B1 and C1-C1 shown in FIG. 1A, respectively.

FIG. 2A is a plan view (second plan view) illustrating the manufacture process for the semiconductor device according to the first embodiment, and FIGS. 2B and 2C are cross sectional views taken along one-dot chain lines B2-B2 and C2-C2 shown in FIG. 2A, respectively.

FIG. 3A is a plan view (third plan view) illustrating the manufacture process for the semiconductor device according to the first embodiment, and FIGS. 3B and 3C are cross sectional views taken along one-dot chain lines B3-B3 and C3-C3 shown in FIG. 3A, respectively.

FIG. 4A is a plan view (fourth plan view) illustrating the manufacture process for the semiconductor device according to the first embodiment, and FIGS. 4B and 4C are cross sectional views taken along one-dot chain lines B4-B4 and C4-C4 shown in FIG. 4A, respectively.

FIG. 5A is a plan view (fifth plan view) illustrating the manufacture process for the semiconductor device according to the first embodiment, and FIGS. 5B and 5C are cross sectional views taken along one-dot chain lines B5-B5 and C5-C5 shown in FIG. 5A, respectively.

FIG. 6A is a plan view (sixth plan view) illustrating the manufacture process for the semiconductor device according to the first embodiment, and FIGS. 6B and 6C are cross sectional views taken along one-dot chain lines B6-B6 and C6-C6 shown in FIG. 6A, respectively.

FIG. 7A is a plan view (seventh plan view) illustrating the manufacture process for the semiconductor device according to the first embodiment, and FIGS. 7B and 7C are cross sectional views taken along one-dot chain lines B7-B7 and C7-C7 shown in FIG. 7A, respectively.

FIG. 8A is a plan view (eighth plan view) illustrating the manufacture process for the semiconductor device according to the first embodiment, and FIGS. 8B and 8C are cross sectional views taken along one-dot chain lines B8-B8 and C8-C8 shown in FIG. 8A, respectively.

FIG. 9A is a plan view (ninth plan view) illustrating the manufacture process for the semiconductor device according to the first embodiment, and FIGS. 9B and 9C are cross sectional views taken along one-dot chain lines B9-B9 and C9-C9 shown in FIG. 9A, respectively.

FIG. 10A is a cross sectional view of a substrate of a semiconductor device during manufacture processes according to a second embodiment.

FIG. 10B is a cross sectional view of the semiconductor device according to the second embodiment.

### BEST MODE FOR CARRYING OUT THE INVENTION

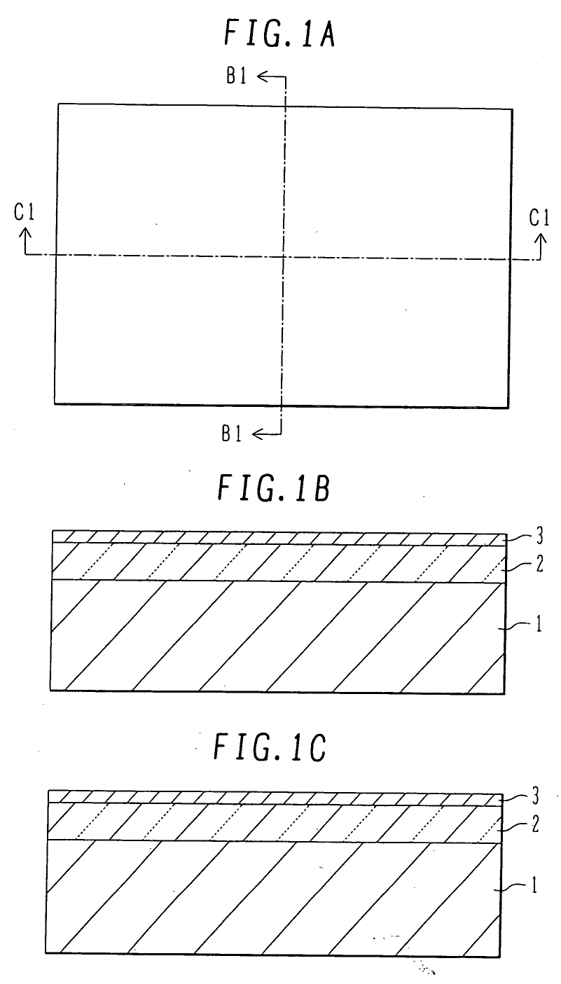

With reference to FIGS. 1A to 9C, description will be made on a manufacture method for a double-gate type SOI transistor according to an embodiment of the invention.

FIG. 1A is a plan view of an SOI substrate used in the embodiment. FIGS. 1B and 1C are cross sectional views taken along one-dot chain lines B1-B1 and C1-C1 shown in FIG. 1A, respectively. On a principal surface of a supporting substrate made of single crystal silicon, a buried insulating layer 2 of silicon oxide is formed, and on the buried insulating layer, an SOI layer 3 of single crystal silicon is formed. For example, a thickness of the buried insulating layer 2 is 200 nm and a thickness of the SOI layer 3 is 40 nm. This SOI substrate is manufactured, for example, by known laminating techniques.

In forming p-channel transistors, the SOI layer 3 is made to have n-type conductivity, and in forming n-channel transistors, the SOI layer 3 is made to have p-type conductivity. The embodiment will be described by taking, as an example, manufacturing p-channel transistors. In manufacturing n-channel transistors, the conductivity type of doped impurities is reversed.

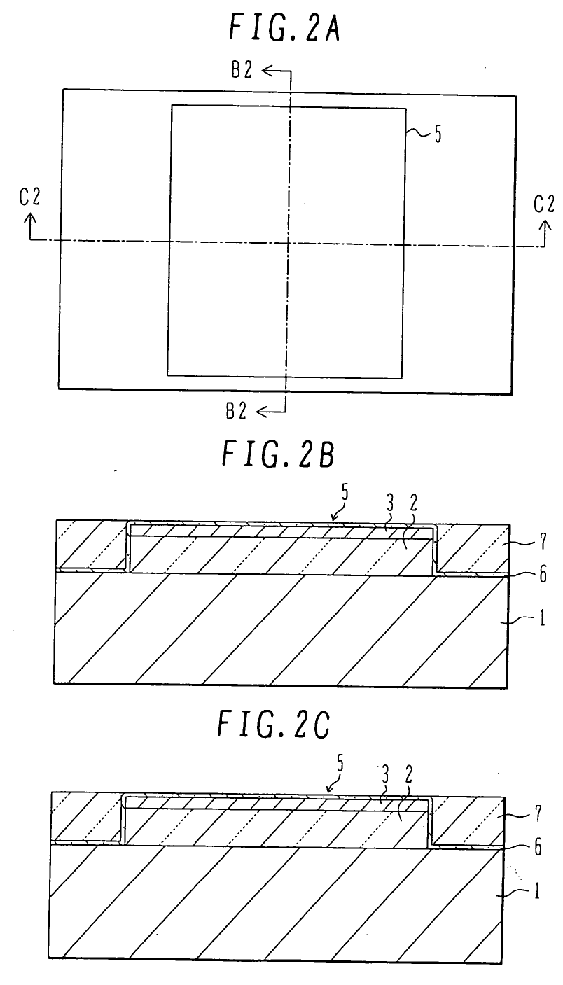

Processes up to the state shown in FIGS. 2A to 2C will be described. FIG. 2A is a plan view, and FIGS. 2B and 2C are cross sectional views taken along one-dot chain lines B2-B2 and C2-C2 shown in FIG. 2A, respectively.

By covering the region where transistors are formed, with a resist pattern, the SOI layer 3 and buried insulating layer 2 are etched to the bottom of the buried insulating layer 2. The SOI layer 3 may be etched by reactive ion etching (RIE) using HBr and He. The flow rates of HBr and He are both set to 160 sccm, a gas pressure is set to 66.5 Pa (0.5 Torr), and an applied high frequency power is set to 350 W. The buried insulating layer 2 may be etched by RIE using CF₄, CHF₃ and Ar. For example, the flow rates of CF₄, CHF₃ and Ar are set to 50 sccm, 30 sccm and 500 sccm, respectively. A gas pressure is set to 133 Pa (1.0 Torr), and an applied high frequency power is set to 300 W. A projection (active region) 5 stacking the buried insulating layer 2 and SOI layer 3 is therefore formed.

A first film 6 of silicon nitride is deposited by chemical vapor deposition (CVD) on the surface of the projection 5 and the exposed surface of the supporting substrate 1. A thickness of the first film 6 is set to about 20 to 30 nm. The first film 6 may be made of insulating material other than silicon nitride having the etching characteristics different from those of the buried insulating layer 2.

On the first film 6, a second film 7 of silicon oxide is deposited by CVD, and chemical mechanical polishing (CMP) is performed to expose the first film 6 on the upper surface of the projection 5. During this CMP, the first film 6 of silicon nitride functions as a polishing stopper. The second film 7 is left in a recess where the buried insulating layer 2 and SOI layer 3 were removed, and the substrate surface is substantially planarized. The second film 7 is an element isolation insulating region for electrically separating semiconductor elements formed on the supporting substrate 1. The second film 7 may be made of insulating material other than silicon oxide having the etching characteristics different from those of the first film 6.

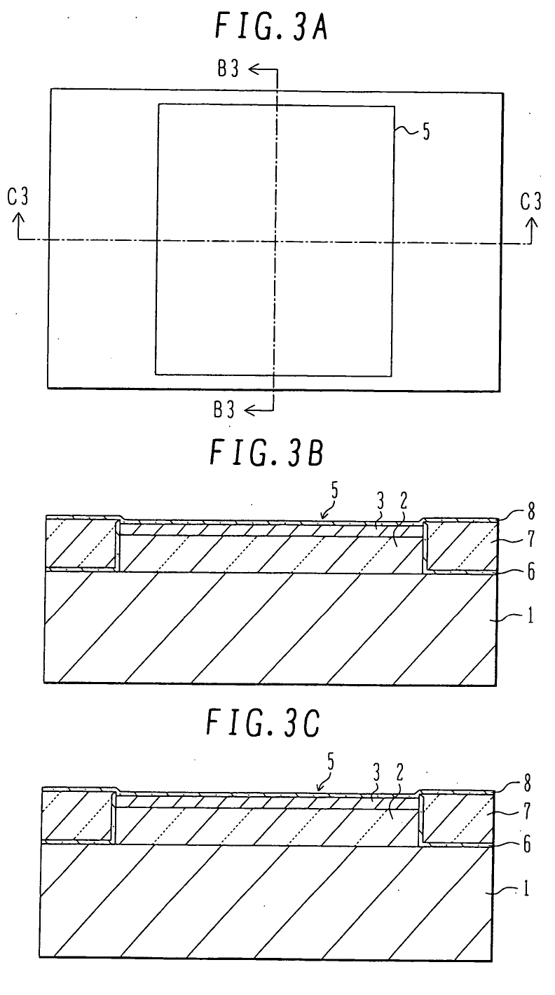

Processes up to the state shown in FIGS. 3A to 3C will be described. FIG. 3A is a plan view, and FIGS. 3B and 3C are cross sectional views taken along one-dot chain lines B3-B3 and C3-C3 shown in FIG. 3A, respectively.

The first film 6 exposed on the projection 5 is removed by wet etching using phosphoric acid solution or RIE. The SOI layer 3 is therefore exposed. A first gate insulating film 8 of HfO₂ having a thickness of 3 nm is formed on the exposed SOI layer 3 and the second film 7. For example, the HfO₂ film can be formed by metal organic chemical deposition (MOCVD) using tetra tertiary butoxy hafnium and O₂. N₂ is used as a carrier gas for tetra tertiary butoxy hafnium. The flow rate of N₂ including tetra tertiary butoxy hafnium is set to 500 sccm, and a flow rate of O₂ gas is set to 100 sccm. A film forming temperature is set to 500° C.

The gate insulating film 8 may be made of silicon oxide by thermally oxidizing the surface layer of the SOI layer 3. In this case, a thickness of the gate insulating film is preferably set to about 2 nm.

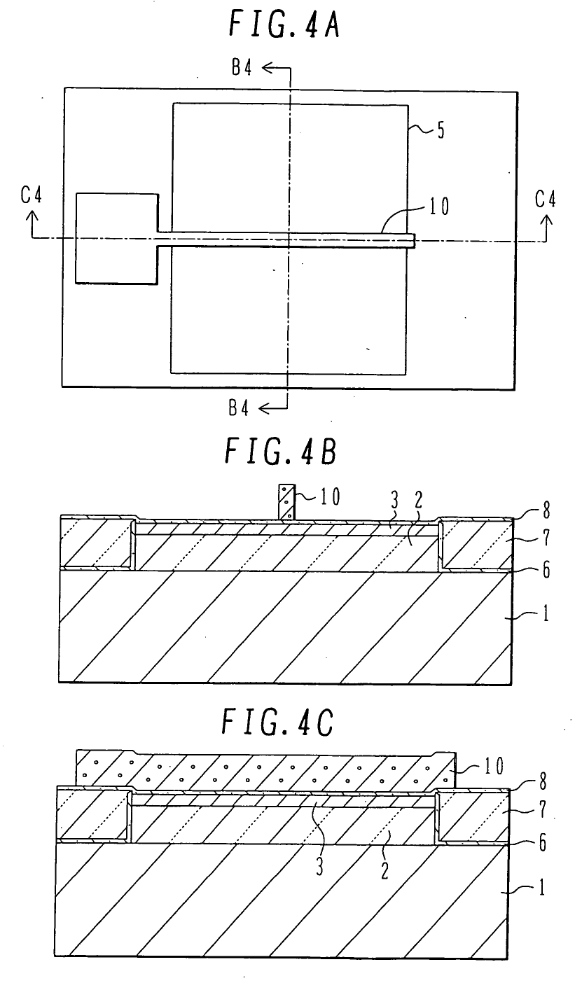

Processes up to the state shown in FIGS. 4A to 4C will be described. FIG. 4A is a plan view, and FIGS. 4B and 4C are cross sectional views taken along one-dot chain lines B4-B4 and C4-C4 shown in FIG. 4A, respectively.

A polysilicon film is deposited to a thickness of 100 nm by CVD on the gate insulating film 5. This polysilicon film is patterned to form a gate electrode 10. The polysilicon film may be etched by RIE using HBr and O₂. For example, the flow rates of HBr and O₂ are 180 sccm and 2 sccm, respectively. A gas pressure is set to 1.6 Pa (12 mTorr) and an applied high frequency power is set to 150 W.

As shown in FIG. 4A, the gate electrode 10 traverses the projection 5 and divides it into two parts as viewed along a direction parallel to the substrate normal. For example, a gate length (a width of the gate electrode 10 within the projection 5) is set to 60 nm.

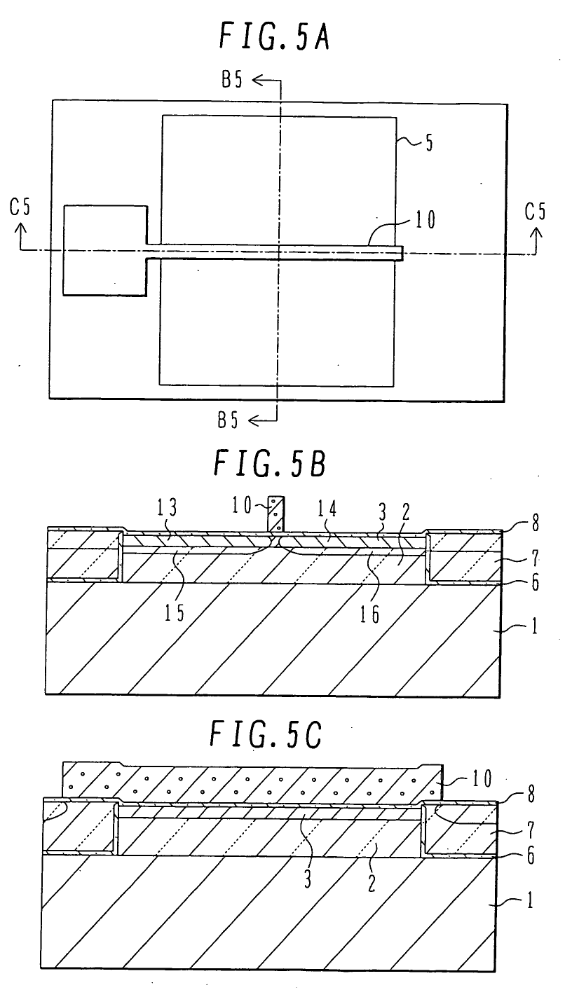

Processes up to the state shown in FIGS. 5A to 5C will be described. FIG. 5A is a plan view, and FIGS. 5B and 5C are cross sectional views taken along one-dot chain lines B5-B5 and C5-C5 shown in FIG. 5A, respectively.

By using the gate electrode 10 as a mask, boron (B) ions are implanted. B⁺ ions are used as an ion type, an acceleration energy is set to 7 keV and a dose is set to 4×10¹⁶ cm⁻². This ion implantation under these conditions results in that an average projective range is about 20 nm and an impurity concentration distribution along a depth direction of the SOI layer 3 having a thickness of 40 nm is approximately in vertical symmetry relative to the central plane. A source region 13 and a drain region 14 are therefore formed in the SOI layer 4 on both sides of the gate electrode.

Boron ions also reach the surface layer of the buried insulating layer 3. Therefore, boron-doped layers 15 and 16 are formed in the regions of the surface layer of the buried insulating layer contacting the source region 13 and drain region 14. Boron ions are also doped in the surface layer of the second film 7. In forming n-channel transistors, antimony (Sb) is used instead of boron.

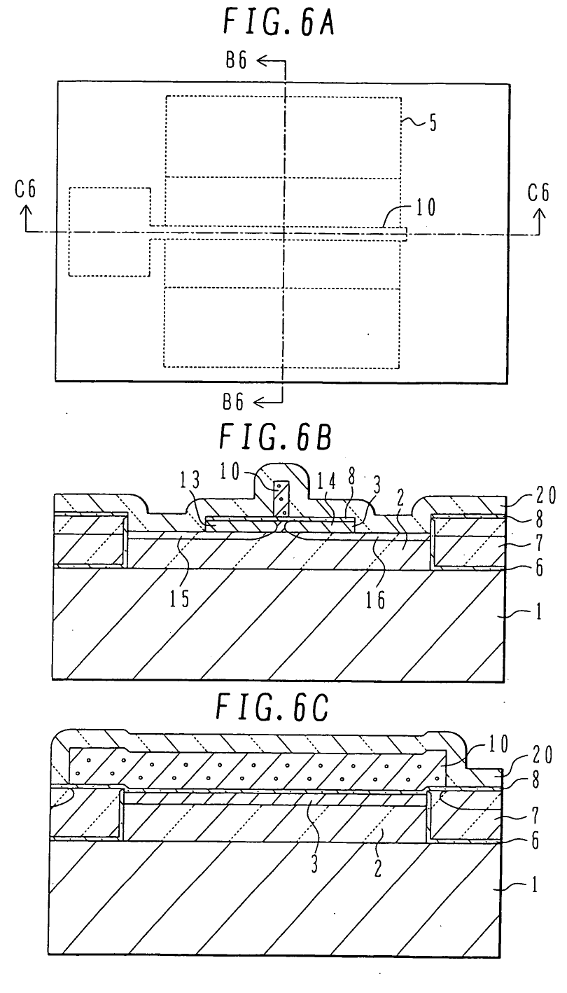

Processes up to the state shown in FIGS. 6A to 6C will be described. FIG. 6A is a plan view, and FIGS. 6B and 6C are cross sectional views taken along one-dot chain lines B6-B6 and C6-C6 shown in FIG. 6A, respectively.

The gate insulating film 8 and SOI layer 3 in the region away from the gate electrode 10 are etched and removed to expose the underlying buried insulating layer 2. The SOI layer 3 is left in the region from the edge of the gate electrode 10 to some distance from the edge. A third film 20 of silicon nitride having a thickness of 50 nm is deposited on the whole surface of the substrate by CVD.

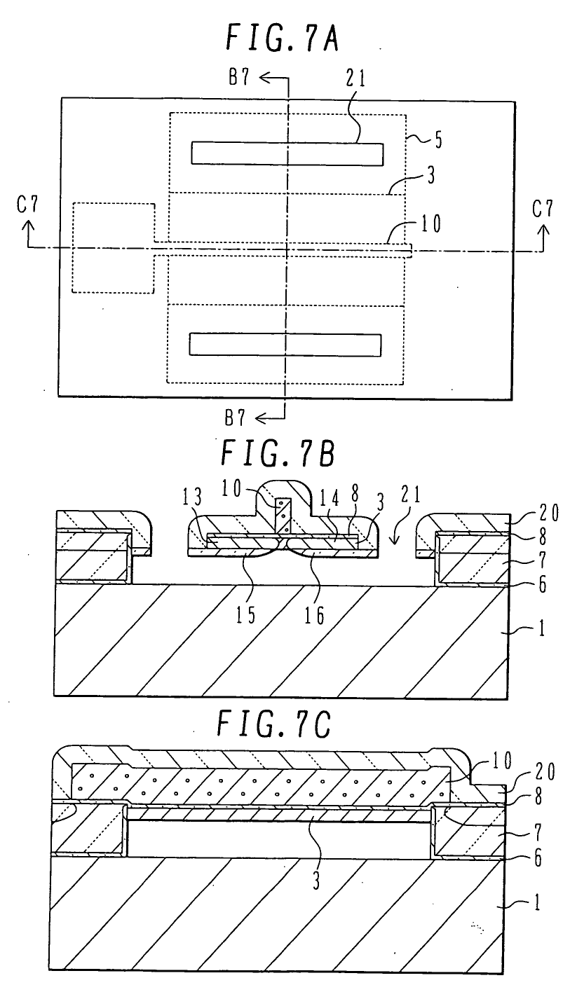

Processes up to the state shown in FIGS. 7A to 7C will be described. FIG. 7A is a plan view, and FIGS. 7B and 7C are cross sectional views taken along one-dot chain lines B7-B7 and C7-C7 shown in FIG. 7A, respectively.

Openings 21 passing through the third film 20 are formed in the regions above the projection 5 where the SOI layer 3 was removed. The openings 21 are formed on both sides of the gate electrode at positions away from the edge of the SOI layer 3. Therefore, the side walls of the SOI layer 3 are maintained being covered with the third film 20. The surface of the buried insulating layer 2 is exposed on the bottoms of the openings 21. The etching is further performed until the principal surface of the supporting substrate 1 is exposed.

Thereafter, the buried insulating layer 2 is laterally etched by buffered hydrofluoric acid using ammonium fluoride as buffer liquid. During this etching, the second film 7 will not be etched because the first film 6 of silicon nitride functions as a protective film. With buffered hydrofluoric acid being used, an etching rate of boron-doped silicon oxide becomes slower than that of non-doped silicon oxide. For example, if buffered hydrofluoric acid contains hydrofluoric acid having a density of 50 weight % and ammonium fluoride solution having a density of 40 weight %, at a volume ratio of 1:7, the etching rate of silicon oxide having a boron density of 5 weight % is about 15 nm/min, whereas the etching rate of non-doped silicon oxide is about 100 nm/min.

Lateral etching of the buried insulating layer 2 continues until the bottom of the SOI layer 3 (channel between the source region 13 and drain region 14) just under the gate electrode 10 is exposed. Since etching progresses from the openings 21 disposed on both sides of the gate electrode 10, a hollow space is formed between the SOI layer 3 and supporting substrate 1.

Since the etching rate of the boron-doped layers 15 and 16 is slower than the etching rate of the non-doped region of the buried insulating layer 2, the boron-doped layers 15 and 16 are left on the bottoms of the source region 13 and drain region 14.

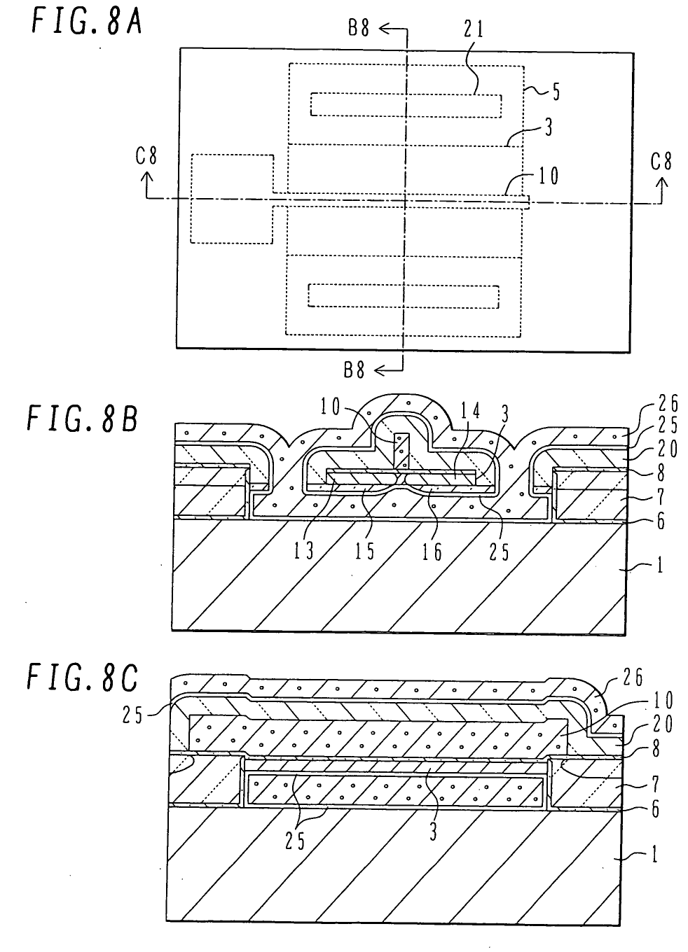

Processes up to the state shown in FIGS. 8A to 8C will be described. FIG. 8A is a plan view, and FIGS. 8B and 8C are cross sectional views taken along one-dot chain lines B8-B8 and C8-C8 shown in FIG. 8A, respectively.

On the exposed surface, a gate insulating film 25 of HfO₂ is deposited by CVD. The gate insulating film 25 is deposited under the conditions that a thickness of the film formed on the bottom of the SOI layer 3 just under the gate electrode 10 is set to 3 nm. The gate insulating film 25 covers the bottom of the channel between the source region 13 and drain region 14 in the SOI layer 3 and the surfaces of the boron-doped layers 15 and 16.

Next, a polysilicon film 26 doped with p-type impurities is deposited by CVD. The polysilicon film 26 is deposited by CVD using silane (SiH₄) and diborane (B₂H₆) at a growth temperature of 550° C. The polysilicon film 26 is grown also in the hollow space under the SOI layer 3. The polysilicon film is grown until the hollow space is completely filled in with the polysilicon film 26.

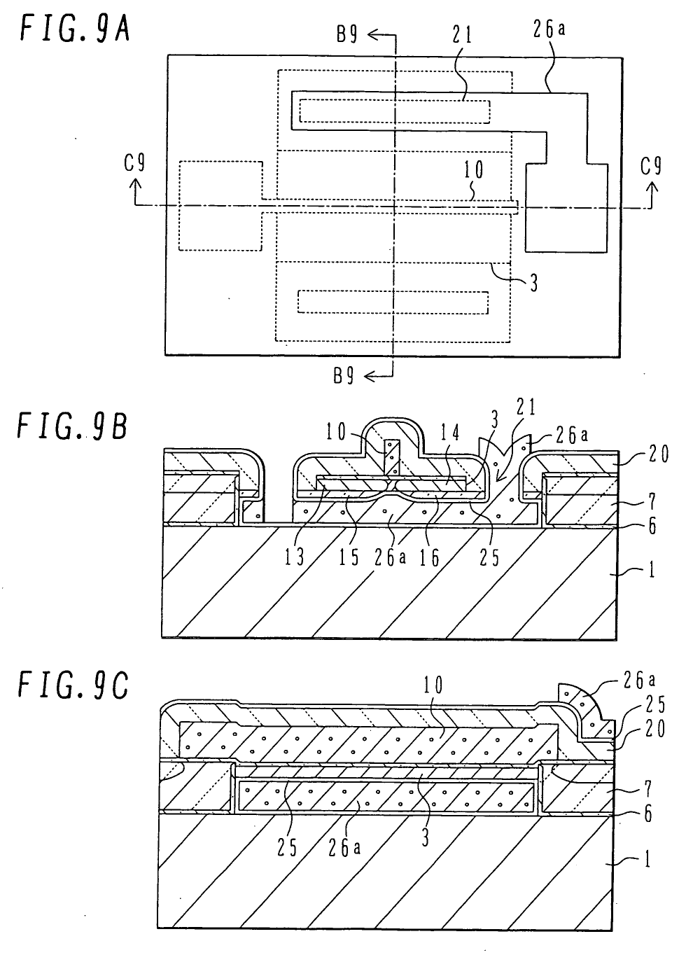

Processes up to the state shown in FIGS. 9A to 9C will be described. FIG. 9A is a plan view, and FIGS. 9B and 9C are cross sectional views taken along one-dot chain lines B9-B9 and C9-C9 shown in FIG. 9A, respectively.

The polysilicon film 26 is patterned to form a lower gate electrode 26a. The gate electrode 26a is left in the hollow space between the SOI layer 3 and supporting substrate 1, extended via the opening 21 to the space above the first film 20, and left on a partial area above the first film 20. Namely, the gate electrode 26a crosses a virtual plane including the upper plane of the SOI layer 3 and is guided to the space above the SOI layer 3. At the intersection between the virtual plane and the gate electrode 26a, the third film 20 of silicon nitride is disposed between the side wall of the SOI layer 3 and the gate electrode 26a so that the SOI layer 3 and gate electrode 26a can be electrically insulated.

In the embodiment described above, the bottoms of the source region 13 and drain region 14 are covered with the boron-doped layers 15 and 16. Boron implantation into the boron-doped layers 15 and 16 is performed at the same time when boron implantation into the source region 13 and drain region 14 is performed. Therefore, the positions of the boron-doped layers 15 and 16 are self-aligned with the positions of the source region 13 and drain region 14. Since the upper gate electrode 10 is used as a mask during boron implantation, the boron-doped layers 15 and 16 are self-aligned also with the upper gate electrode 10.

The lower gate insulating film 25 contacts the bottom of the SOI layer 3 between the boron-doped layers 15 and 16. The boron-doped layer 15 is disposed between the lower gate electrode 26a and source region 13, and the boron-doped layer 16 is disposed between the lower gate electrode 26a and drain region 14. It is therefore possible to suppress an increase in a parasitic capacitance between the source region 13 and gate electrode 26a and a parasitic capacitance between the drain region 14 and gate electrode 26a. In order to retain sufficient effects of suppressing a parasitic capacitance increase, it is preferable to set the thickness of the boron-doped layers 15 and 16 to 10 nm or thicker.

Since the boron-doped layers 15 and 16 are self-aligned with the upper gate electrode 10, the position at which the lower gate electrode 26a faces the channel is also self-aligned with the upper gate electrode 10.

The manufacture method of the embodiment described above does not use a special process but uses only conventional semiconductor processes. Mass production can be made relatively easily.

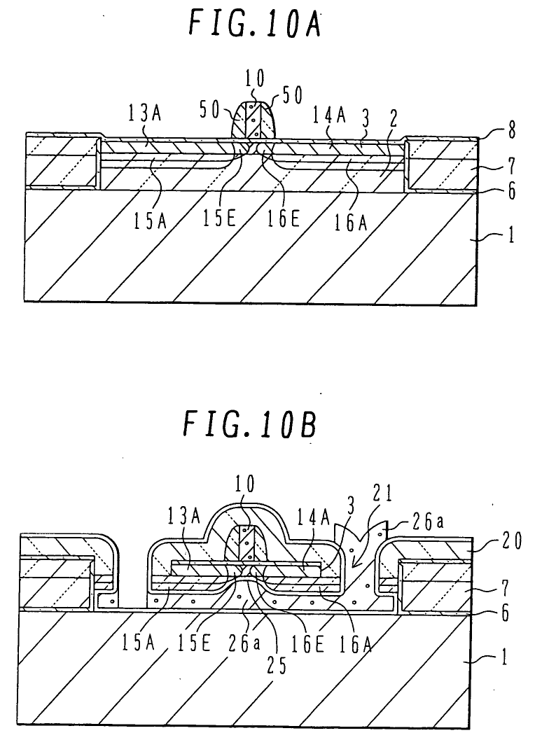

Next, with reference to FIGS. 10A and 10B, description will be made on a semiconductor device manufacture method according to a second embodiment. Processes up to the states shown in FIGS. 4A to 4C of the first embodiments are common to those of the second embodiment.

As shown in FIG. 10A, by using a gate electrode 10 as a mask, boron ions are implanted to form source/drain extensions 15E and 16E. Side wall spacers 50 of silicon nitride are formed on the side walls of the gate electrode 10. A thickness of the sidewall spacer 50 is set to, for example, 50 nm.

By using the gate electrode 10 and sidewall spacers 50 as a mask, boron ions are implanted to form a source region 15A and a drain region 16A. The subsequent processes are similar to those of the first embodiment.

As shown in FIG. 10B, a double-gate type transistor is therefore obtained which has the extensions 15E and 16E between the channel and the source/drain regions.

Also in the second embodiment, the position of the upper gate electrode 10 can be self-aligned with the position of the lower gate electrode 26a.

The present invention has been described in connection with the preferred embodiments. The invention is not limited only to the above embodiments. It will be apparent to those skilled in the art that other various modifications, improvements, combinations, and the like can be made.

1. A manufacture method for a semiconductor device, comprising steps of:
(a) forming a first gate insulating film on an SOI layer made of semiconductor of an SOI substrate stacking a supporting substrate, a buried insulting layer and the SOI layer in this order recited;
(b) forming a first gate electrode on the first gate insulating film;
(c) removing the buried insulating layer positioned below the first gate electrode to expose a bottom of the SOI layer;
(d) forming a second gate insulating film on the exposed bottom of the SOI layer; and
(e) forming a second gate electrode on a surface of the second gate insulating film.

2. The manufacture method according to claim 1, wherein the step (c) comprises steps of:
removing the first gate insulating film and the SOI layer at positions away from the gate electrode to expose an upper surface of the buried insulating layer; and
etching the buried insulating layer starting from the exposed surface of the buried insulating layer, and then laterally etching the buried insulting layer to at least a region under the first gate electrode.

3. The manufacture method according to claim 1, further comprising after the step (b), a step of implanting impurities into the SOI layer on both sides of the first gate electrode by using the first gate electrode as a mask, to form a source region and a drain region.

4. The manufacture method according to claim 3, wherein the impurities are implanted under a condition that the impurities reach a surface layer of the buried insulating layer.

5. The manufacture method according to claim 4, wherein in the step (c), the buried insulating layer is etched under a condition that an etching rate of a region of the buried insulating layer not implanted with the impurities is faster than an etching rate of a region implanted with the impurities, to leave regions implanted with the impurities of the buries insulating layer on bottoms of the source and drain regions.

6. The manufacture method according to claim 1, before the step (a), further comprising steps of:
partially etching the buried insulating layer and the SOI layer to form a projection made of a left buried insulating layer and a left SOI layer;
covering a surface of the projection and an exposed surface of the supporting substrate with a first film having etching characteristics different from etching characteristics of the buried insulating layer;
burying a region where the buried insulating layer and the SOI layer are removed, with a second film made of insulating material; and
removing the first film on the projection to expose an upper surface of the SOI layer,
wherein, in the step (b), the first gate electrode is formed in such a manner that the first gate electrode traverses the projection, and as viewed along a direction parallel to a substrate normal, the first electrode divides the projection into two regions.

7. The manufacture method according to claim 6, wherein the step (c) comprises steps of:
partially removing the SOI layer to leave the SOI layer in a region having a width from an edge of the first gate electrode and expose an upper surface of the buries insulating layer;
covering a whole surface of the SOI substrate with a third film made of insulting material having etching characteristics different from etching characteristics of the buried insulating layer;
forming openings through the third film to expose at least a partial upper surface of the projection where the SOI layer is removed; and
a step of starting etching the buried insulating layer via the openings and then laterally etching the buried insulating layer to at least a region under the first gate electrode.

8. A semiconductor device comprising:
a semiconductor film having top and bottom surfaces and defining a channel region, and a source region and a drain region on both sides of the channel region;
a first gate insulating film formed on an upper surface of the channel region of the semiconductor film;
a first gate electrode formed on the first gate insulating film;
a first insulating film of insulating material formed on bottom surfaces of the source region and drain region of the semiconductor film;
a second gate insulating film covering a bottom surface of the channel region of the semiconductor film and a surface of the first insulating film; and
a second gate electrode formed on the second gate insulating film.

9. The semiconductor device according to claim 8, wherein same impurities as doped in the source region and drain region of the semiconductor film are doped in the first insulating film.

10. The semiconductor device according to claim 9, wherein the second gate electrode crosses a virtual plane including the top surface of the semiconductor film and extends to a space over an upper side of the semiconductor film.

11. The semiconductor device according to claim 10, further comprising:
a second insulating film covering the top surface and side surfaces of the semiconductor film and a surface of the first gate electrode, the second insulating film being made of insulating material having etching characteristics different from etching characteristics of the first insulating film,
wherein the second insulating film electrically insulates the second gate electrode from the semiconductor film at an intersection between the second gate electrode and the virtual plane.
